(19) United States
(12) Patent Application Publication
(10) Pub. No.: US 2015/0241770 A1
(43) Pub. Date: Aug. 27, 2015

(54) Photosensitive Resin Laminate for Flexographic Plate with Infrared Ablation Layer

(71) Applicants: NIHON DENSHI SEIKI CO., LTD., Kashiba-city, Nara (JP); THE OSAKA PRINTING INK MFG. CO., LTD., Osaka-shi, Osaka (JP)

(72) Inventors: Jun Yoshida, Nara (JP); Hideharu Tsujiuchi, Osaka (JP)

(21) Appl. No.: 14/427,415

(22) PCT Filed: Jul. 1, 2014
(86) PCT No.: PCT/JP2014/067585

§ 371 Date: Mar. 11, 2015

(30) Foreign Application Priority Data
Jul. 2, 2013 (JP) 2013-139266

(51) Int. Cl. G03F 7/028; G03F 7/11

(52) U.S. Cl. CPC G03F 7/028; G03F 7/11

(57) ABSTRACT

A photosensitive resin laminate comprising infrared ablation layer which could be removed by infrared laser, wherein the photosensitive resin laminate has excellent properties such as membrane strength, scratch resistance, adhesion with photosensitive resin layer, handling easiness when making the plates, plotting property with infrared laser, solubility to flexographic developing solvent and sensitivity improvement to infrared laser. A photosensitive resin laminate for flexographic plate consisting of; support layer, photosensitive resin layer placed on said support layer comprising thermoplastic elastomer, polymerizable unsaturated monomer and photopolymerization initiator, infrared ablation layer placed on said photosensitive resin layer which is removable by infrared laser and masks non-infrared radiation, and cover film placed on said infrared ablation layer, wherein said infrared ablation layer comprises modified polyolefin and infrared absorbing material, and wherein said modified polyolefin comprises at least more than one polymer selected from the group consisting of polyolefin modified by chlorine and/or maleic acid.

### FIELD OF THE INVENTION

The present invention relates to a photosensitive resin laminate for flexographic plate, which could be applied to a plate preparation method for directly plot image information digitized on computer using infrared laser, and without the need of a negative film. More particularly, the present invention relates to the photosensitive resin laminate comprising an infrared ablation layer which could be removed by infrared laser, wherein the photosensitive resin laminate has excellent properties such as membrane strength, scratch resistance, adhesiveness to a photosensitive resin layer, handling easiness when preparing the plates, plotting property by infrared laser, solubility to a flexographic developing solvent and high sensitivity to infrared laser.

### BACKGROUND OF THE INVENTION

Conventional photosensitive resin laminates for flexographic plates generally have a support body consists of polyester film etc., and a photosensitive resin layer comprising thermoplastic elastomer, polymerizable unsaturated monomer and photopolymerization initiator formed on the support.

For example, a procedure to prepare flexographic plates from such laminates is as follows. First, whole surface of the photosensitive resin layer is exposed to ultraviolet through the support (back exposure) to form thin uniform hardened-layer. Then, a negative film is placed on the layer, and a vacuum sheet is covered over negative film and is evacuated so that the negative film and the layer are adhered to each other. Next, image is exposed to the surface of the photosensitive resin layer through the negative film (relief exposure). Then, non-exposed part of the photosensitive resin layer is washed out with the developing solvent to obtain desired image, i.e. relief image, which becomes the flexographic plate.

Here, a thin film which is referred to slip-coat layer or protective layer is placed on the photosensitive resin layer to smoothly contact the negative film with the photosensitive resin layer so that the air between the negative film and the photosensitive resin layer could be easily released. This is performed also to avoid damaging the negative film when removing the photosensitive resin layer from the negative film after relief exposure.

On the other hand, techniques related to the photosensitive resin laminates for flexographic plate that could directly plot the digitized image information without using the negative film, and its preparation methods are also known. Particularly, it is a method to obtain desired image by selectively removing the layer, which is provided on the photosensitive resin layer sensitive to non-infrared radiation, and is removable by infrared laser and masks non-infrared radiation (infrared ablation layer), by infrared laser based on image information digitized in computer. This is a plate preparation method also referred to LAMS (laser ablation mask).

After plotting the image on the infrared ablation layer placed on the photosensitive resin layer, conventional plate preparation methods could be applied without any modification. In other words, back exposure is done from support side and relief exposure is done from image side, which was plotted by infrared laser, by using conventional exposing device, and then image development is performed to obtain the flexographic plate.

This plate preparation method is more cost effective than conventional method using the negative film since it does not produce problems such as plate preparing error caused by foreign materials entrapped between the photosensitive resin layer and the negative film by poor adhesion of the negative film, and there is no need to make new negative film when the image needs to be modified because the digitized image information could be modified in computer. Furthermore, the amount of demand and supply of the negative film itself is reduced due to digitalization of image information rapid during recent years, and thus it is becoming difficult to obtain negative films in inexpensive price and constantly supplied. Thus, in this regard, LAMS (laser ablation mask) method, which does not need the negative film, is preferable. Also, this plate preparation method is preferable because of its dimensional stability compared to conventional method using the negative film, and leading the improvement of reproducibility of relief image and printing quality.

For example, patent document 1 describes about infrared ablation layer, where a binder polymer used with infrared absorbing material or non-infrared radiation masking material is substantially incompatible to at least one low molecule material in the photosensitive resin layer. Examples of the binder polymer used to achieve such property include polyamide, polyvinyl alcohol, graft copolymer of polyvinyl alcohol/polyethyleneglycol and the combination thereof.

However, the infrared ablation layer using above polymers may have problems caused by poor compatibility of the above polymer to low molecule material in the photosensitive resin layer. For example, adhesiveness of the infrared ablation layer and the photosensitive resin layer could be low because undesirable compatibility combination of the infrared ablation layer and the photosensitive resin layer must be used. In such case, the infrared ablation layer may be partially detached from the photosensitive resin layer when detaching the cover film before laser plotting, and the infrared ablation layer could be torn off keeping stuck on cover film. Also, low-polarity solvents containing solvent naphtha as a main component, which is mainly used as the developing solvents for the digital flexographic plate, has poor compatibility to the above polymers. Thus, there is a problem that the infrared ablation layer may remain unmelted when developing the solvent, and re-attach to plate or brush of developing device.

Patent document 2 discloses that at least one of thermoplastic polymers in the photosensitive resin layer is a copolymer of monovinyl-substituted aromatic hydrocarbon and conjugated diene. It also discloses that adhesiveness of the infrared ablation layer and the photosensitive resin layer is excellent when the binder polymer used in the infrared ablation layer is the copolymer of monovinyl-substituted aromatic hydrocarbon and conjugated diene or hydrogen-added said copolymer. In such case, the infrared ablation layer would not be torn when detaching cover film, and the developing solvent could be selected from broad range.

However, flexibility of the infrared ablation layer of the photosensitive resin laminate for flexographic plate disclosed in patent document 2 is not enough, and thus fine wrinkles and cracks could occur frequently in the infrared ablation layer during preparation of the plates. Also, adhesiveness of the infrared ablation layer and the cover film is high, i.e. detach resistance when detaching the cover film is high, so detaching of the cover film is difficult and it may interfere plate preparation process, especially when preparing large plates. Furthermore, detaching of the cover film must be performed intermittently and gradually, and thus detaching trace may remain on the surface of the infrared ablation layer, or scratch may occur on the photosensitive resin layer by lifting the photosensitive resin layer by mistake.

Patent document 3 discloses that at least one of thermoplastic polymers in the photosensitive resin layer is a copolymer of monovinyl-substituted aromatic hydrocarbon and conjugated diene. It also discloses a method for adding 1-20 percent by weight of polyester polyol with number-average molecular weight of 300-10,000, which comprises hydroxyl group at molecular terminal, to copolymer of monovinyl-substituted aromatic hydrocarbon and conjugated diene as the binder polymer used in the infrared ablation layer.

However, said polyester polyol is a material with relatively high polarity, and it has low compatibility to the low-polarity solvent, which contains solvent naphtha as a main component and used as the developing solvent for digital flexographic plate in recent years. Therefore, there is a problem that the infrared ablation layer may remain unmelted when developing the solvent, and the unmelted layer re-attaches to the plate or the brush of developing device. Also, sensitivity of the infrared ablation layer to infrared is relatively low, and thus it may require infrared laser with high energy for ablation process.

On the other hand, patent document 4 implemented improved flexibility of the infrared ablation layer and improved sensitivity to the infrared laser by using photosensitive print elements comprising aliphatic diester as the infrared ablation layer. However, adding plasticizer component such as aliphatic diester to the infrared ablation layer may cause problems such as decrease of membrane strength of the ablation layer and scratch resistance or gradual bleeding out of plasticizer component from the ablation layer. Also, there is no description of means to ease the detaching of the cover film and the infrared ablation layer in patent document 4.

Combination of compositions that could be used as the infrared ablation layer is various, and thus it was difficult to select composition with properties such as desirable adhesiveness to the photosensitive resin layer, membrane strength of the ablation layer, scratch resistance, handling easiness when preparing the plates, high sensitivity to infrared laser, excellent plotting property with infrared laser and image reproducibility.

### PRIOR ART DOCUMENTS

Patent document 1: Tokkaihei8-305030

Patent document 2: Tokkaihei11-153865

Patent document 3: Japanese Patent No. 4590142

Patent document 4: Tokkai2001-80225

### SUMMARY OF INVENTION

The present invention provides a photosensitive resin laminate for flexographic plate, which could be applied to a plate preparation method using infrared laser to directly plot the image information digitized on computer, and without using a negative film. Particularly, the present invention relates to the photosensitive resin laminate comprising an infrared ablation layer which could be removed by infrared laser, wherein the photosensitive resin laminate has excellent properties such as membrane strength, scratch resistance, adhesiveness to the photosensitive resin layer, handling easiness when preparing the plates, plotting property with infrared laser, solubility to flexographic developing solvent and sensitivity improvement to infrared laser.

In order to solve these problems, the present inventors intensively studied. As a result, the present inventors found out the present invention.

The invention according to claim 1 relates to a photosensitive resin laminate for flexographic plate consisting of; support layer (A), photosensitive resin layer (B) placed on said support layer (A) comprising thermoplastic elastomer, polymerizable unsaturated monomer and photopolymerization initiator, infrared ablation layer (C) placed on said photosensitive resin layer (B) which is removable by infrared laser and masks non-infrared radiation, and cover film (D) placed on said infrared ablation layer (C), wherein said infrared ablation layer (C) comprises modified polyolefin (c1) and infrared absorbing material (c2), and wherein said modified polyolefin (c1) comprises at least more than one polymer selected from the group consisting of polyolefin modified by chlorine and/or maleic acid.

The invention according to claim 2 relates to the photosensitive resin laminate for flexographic plate according to claim 1, wherein said modified polyolefin (c1) comprises at least more than one polymer selected from the polymer group consisting of chlorinated polypropylene, maleic acid-modified chlorinated polypropylene, chlorinated polypropylene-acryl copolymer, maleic acid-modified propylene, chlorinated polyethylene and chlorinated EVA (ethylene-vinyl acetate copolymer).

The invention according to claim 3 relates to the photosensitive resin laminate for flexographic plate according to claim 1 or 2, wherein said modified polyolefin (c1) is chlorine-modified polyolefin with 3-70% chlorine-modified rate, maleic acid-modified polyolefin with 0.5-10% maleic acid-modified rate, or maleic acid-modified chlorinated polyolefin with 3-70% chlorine-modified rate and 0.5-10% maleic acid-modified rate.

The invention according to claim 4 relates to the photosensitive resin laminate for flexographic plate according to any one of claims 1-3, wherein weight-average molecular weight (Mw) of said modified polyolefin (c1) is 5,000-250,000.

The invention according to claim 5 relates to the photosensitive resin laminate for flexographic plate according to anyone of claims 1-4, wherein softening point of said modified polyolefin (c1) is 40° C.-300° C.

The invention according to claim 6 relates to the photosensitive resin laminate for flexographic plate according to anyone of claims 1-5, wherein content of said infrared absorbing material (c2) is in the range of 10-70% by mass with respect to said infrared ablation layer (C).

The invention according to claim 7 relates to the photosensitive resin laminate for flexographic plate according to any one of claims 1-6, wherein said support layer (A) is polyester film.

The invention according to claim 8 relates to the photosensitive resin laminate for flexographic plate according to any one of claims 1-7, wherein said cover film (D) is polyester film.

### Effect of the Invention

The invention according to claim 1 relates to a photosensitive resin laminate for flexographic plate, wherein said infrared ablation layer (C) comprises modified polyolefin (c1) and infrared absorbing material (c2), and wherein said modified polyolefin (c1) comprises at least more than one polymer selected from the group consisting of polyolefin modified by chlorine and/or maleic acid.

In the photosensitive resin laminate for flexographic plate, which could be applied to the plate preparation method for directly plot image information digitized on computer using infrared laser, and without the need of the negative film, the invention of claim 1 could provide the photosensitive resin laminate for flexographic plate, which comprises the infrared ablation layer that is removable by infrared laser, with properties such as excellent mechanical property, scratch resistance, adhesiveness to the photosensitive resin layer, handling easiness when making the plates, plotting property with infrared laser, solubility to the flexographic developing solvent and improvement of sensitivity to infrared laser.

The invention according to claim 2 relates to the photosensitive resin laminate for flexographic plate according to claim 1, wherein said modified polyolefin (c1) comprises at least more than one polymer selected from the polymer group consisting of chlorinated polypropylene, maleic acid-modified chlorinated polypropylene, chlorinated polypropylene-acryl copolymer, maleic acid-modified propylene, chlorinated polyethylene and chlorinated EVA (ethylene-vinyl acetate copolymer)

The invention of claim 2 could provide the photosensitive resin laminate for flexographic plate, which comprises the infrared ablation layer that is removable by infrared laser, with properties such as better mechanical property, scratch resistance, adhesiveness to photosensitive resin layer, handling easiness when preparing the plates, plotting property with infrared laser, solubility to the flexographic developing solvent and improvement of sensitivity to infrared laser.

The invention according to claim 3 relates to the photosensitive resin laminate for flexographic plate according to claim 1 or 2, wherein said modified polyolefin (c1) is chlorine-modified polyolefin with 3-70% chlorine-modified rate, maleic acid-modified polyolefin with 0.5-10% maleic acid-modified rate, or maleic acid-modified chlorinated polyolefin with 3-70% chlorine-modified rate and 0.5-10% maleic acid-modified rate.

The invention of claim 3 could provide maintenance of properties of the photosensitive resin laminate for flexographic plate such as formability, heat resistance, chemical resistance, scratch resistance, flexibility, adhesiveness to the photosensitive resin layer, and solubility to the flexographic developing solvent.

The invention according to claim 4 relates to the photosensitive resin laminate for flexographic plate according to any one of claims 1-3, wherein weight-average molecular weight (Mw) of said modified polyolefin (c1) is 5,000-250,000.

The invention of claim 4 could provide maintenance of properties of the photosensitive resin laminate for flexographic plate such as formability, heat resistance, chemical resistance, scratch resistance and flexibility. By these effects, the invention of claim 4 can prevent damages such as fine wrinkles, scratches and cracks, to the infrared ablation layer (C).

The invention according to claim 5 relates to the photosensitive resin laminate for flexographic plate according to anyone of claims 1-4, wherein softening point of said modified polyolefin (c1) is 40° C.-300° C.

The invention of claim 5 could provide maintenance of the properties of the photosensitive resin laminate for flexographic plate such as formability, heat resistance, scratch resistance and flexibility. By these effects, the invention of claim 5 can prevent the increase of viscosity of the infrared ablation layer (C).

The invention according to claim 6 relates to the photosensitive resin laminate for flexographic plate according to any one of claims 1-5, wherein content of said infrared absorbing material (c2) is in the range of 10-70% by mass with respect to said infrared ablation layer (C).

The invention of claim 6 could provide good balance of plotting sensitivity by infrared laser, mask effect of non-infrared radiation, formability, mechanical property, heat resistance, scratch resistance and flexibility of the infrared ablation layer (C).

The invention according to claim 7 relates to the photosensitive resin laminate for flexographic plate according to any one of claims 1-6, wherein said support layer (A) is polyester film.

The invention of claim 7 could provide maintenance of dimension stability, mechanical strength and heat resistance. Thus, the invention of claim 7 could give practically sufficient dimension stability, mechanical strength and heat resistance to the photosensitive resin laminate for flexographic plate.

The invention according to claim 8 relates to the photosensitive resin laminate for flexographic plate according to any one of claims 1-7, wherein said cover film (D) is polyester film.

The invention of claim 8 could provide improved strength and dimension stability of the cover film (D). Thus, the invention of claim 8 could prevent scratch and stain on the photosensitive resin layer (B) and the infrared ablation layer (C) when storing and handling the photosensitive resin laminate for flexographic plate.

### BRIEF DESCRIPTION OF THE DRAWINGS

FIG. 1 is a structure view of the photosensitive resin laminate for flexographic plate of the present invention consisting of a support layer (A) (e.g. polyester film), a photosensitive resin layer (B), an infrared ablation layer (C) and a cover film layer (D) (e.g. polyester film).

### DETAILED DESCRIPTION OF THE INVENTION

Best embodiments of the present invention (hereinafter referred to “present embodiments”) including preferable embodiments will be explained hereinafter, but the present invention is not limited to the embodiments described below. It should be understood that appropriate changes and improvements without departing from the scope of the invention to embodiments described below based on knowledge of those skilled in the art fall within the range of the present invention.

The photosensitive resin laminate for flexographic plate of the present invention (hereinafter referred to as “laminate of the present invention”) has a support layer (A), a photosensitive resin layer (B) placed on the support layer (A) and an infrared ablation layer (C) placed on the photosensitive resin layer (B), and it also has a cover film (D) placed on the infrared ablation layer (C).

For example, the laminate of the present invention has the support layer (A), the photosensitive resin layer (B) placed on the support layer (A) and the infrared ablation layer (C) placed on a side of the photosensitive resin layer (B) opposite to the support layer (A), and it also has the cover film (D) placed on a side of the infrared ablation layer (C) opposite to the photosensitive resin layer (B).

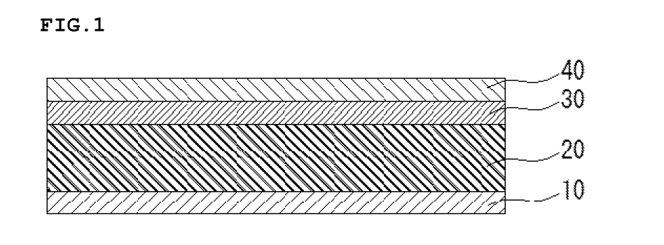

FIG. 1 shows an embodiment of the laminate of the present invention. The laminate of FIG. 1 consists of the support layer 10, the photosensitive resin layer 20 placed on the support layer 10, the infrared ablation layer 30 placed on a side of the photosensitive resin layer 20 opposite to the support layer 10 and the cover film 40 placed on a side of the infrared ablation layer 30 opposite to the photosensitive resin layer 20. Thus, the laminate of FIG. 1 has layer structure of 10/20/30/40.

<Support Layer (A)>

For example, the support layer (A) may include polyester film or polyolefin film such as polyethylene and polypropylene. Polyethylene is preferable because it has properties such as excellent dimensional stability, mechanical strength and heat resistance. Thickness of the support layer (A) is normally 75 um-300 um. Also, clear type of said polyethylene film may be used, or matte type of said polyethylene film or polyethylene film with infrared absorption effect may be used to control exposure time of back exposure.

Further, in order to improve the adhesion of the support layer (A) and the photosensitive resin layer (B), an adhesive layer may be placed in between the support layer (A) and the photosensitive resin layer (B), if necessary. Adhesive used for forming an adhesive layer may include, but not limited to acrylic, epoxy, polyester or polyurethane adhesive, if it could improve the adhesiveness of the support layer (A) and the photosensitive resin layer (B). The adhesive may be single component or combination of two or more components. Also, in order to improve adhesion of the support layer (A) and the adhesive layer, the adhesive layer may be placed after corona treatment of surface of the support layer (A), if necessary.

<Photosensitive Resin Layer (B)>

The photosensitive resin layer is a layer that will be exposed by non-infrared radiation, which is selectively masked by the infrared ablation layer (C) that is removed in a form based on image information by infrared laser.

Component of the photosensitive resin layer is not limited as long as the layer could exhibit good print performance on materials to be printed such as cardboard and non-rigid plastic film. Composition of thermoplastic elastomer, polymerizable unsaturated monomer and photopolymerization initiator are used in the present invention.

For example, thermoplastic elastomer may be a copolymer of monovinyl-substituted aromatic hydrocarbon such as styrene and conjugated diene such as butadiene and isoprene. Specific examples are styrene-butadiene-styrene block copolymer, styrene-isoprene-styrene block copolymer and styrene-isoprene/butadiene-styrene block copolymer. The thermoplastic elastomer may be single component or combination of two or more components.

Content of the thermoplastic elastomer is normally 30.0-95.0 parts by mass and preferably 40.0-90.0 parts by mass to 100 parts by mass of the photosensitive resin layer (B). When the content of the thermoplastic elastomer is in the above range, the flexographic plate with preferable performance such as solid form retention at storage, handling easiness when preparing the plate, image reproducibility and plate durability when printing, could be obtained.

The polymerizable unsaturated monomer may be ester such as acrylic acid, metacrylic acid, fumaric acid and maleic acid, derivatives of acrylic amide and metacrylic amide, allylic ester, styrene, styrene derivatives and N-substituted maleimide compounds. Particularly, the polymerizable unsaturated monomer may be diacrylate and dimethacrylate of alkanediol such as ethanediol, propanediol, butanediol, hexanediol, nonanediol; diacrylate and dimethacrylate such as diethylene glycol, dipropylene glycol and polyethylene glycol; Trimethylolpropane trimethacrylate, dimethyloltricyclodecane dimethacrylate, isobornyl methacrylate, phenoxy polyethylene glycol methacrylate, pentaerythrit tetramethacrylate, diacrylphthalate; diethyl fumarate ester, dibutyl fumarate ester, dioctyl fumarate ester, distearyl fumarate ester, butyloctyl fumarate ester, diphenyl fumarate ester, dibenzyl fumarate ester, bis(3-phenylpropyl) fumarate ester, dilauryl fumarate ester, dibehenyl fumarate ester; dibutyl maleate ester, dioctyl maleate ester; N,N′-Hexamethylenebisacrylamide and methacrylamide; triallyl isocyanurate; vinyltoluene; divinylbenzene; and N-laurylmaleimide. The polymerizable unsaturated monomer may be single component or combination of two or more components.

Content of the polymerizable unsaturated monomer in photosensitive resin layer (B) may normally be 1.0-30.0 parts by mass and preferably 1.0-15.0 part by mass to 100 parts by mass of photosensitive resin layer (B). When the content of the polymerizable unsaturated monomer is in the above range, flexographic plate with preferable performance such as image reproducibility, plate durability when printing, ink resistance and chemical resistance could be obtained.

The photopolymerization initiator is not limited as long as it could initiate polymerization of the polymerizable unsaturated monomer as a response to non-infrared radiation, and may be appropriately selected depending on physical properties of the photosensitive resin layer (C) of interest. For example, the photopolymerization initiator may be aromatic ketone such as benzophenone, benzoin ether such as benzyl dimethyl ketal, benzoin methyl ether, benzoin ethyl ether and benzoin isopropyl ether, α-hydroxyketone, α-aminoketone, oxime ester and acylphosphine oxido compounds. The photopolymerization initiator may be single component or combination of two or more components.

Content of the photopolymerization initiator in the photosensitive resin layer (B) may normally be 0.1-10.0 parts by mass and preferably 1.0-5.0 part by mass to 100 parts by mass of the photosensitive resin layer (B). When the content of the photopolymerization initiator is in the above range, the flexographic plate with preferable performance such as exposure time when preparing the plate and image reproducibility could be obtained.

In photosensitive resin layer (B), one or more additives such as plasticizer, processing stabilizer, liquid rubber, heat polymerization inhibitor, sensitizer, coloring agent, ultraviolet absorber, halation preventing agent, antiozone deterioration agent, inorganic filler and flame retardant may be added depending on required properties.

Photosensitive resin layer (B) may be formed by various methods. For example, it may be formed from photosensitive resin composition comprising thermoplastic elastomer, polymerizable unsaturated monomer and photopolymerization initiator. For instance, if the component of photosensitive resin layer (B) is as described above, materials may be dissolved in appropriate solvent such as chloroform, tetrachloroethylene, methylethylketone and toluene, and the solvent is evaporated by pouring the solvent into the mold. This could be directly used as photosensitive resin plate. Also, the materials may be mixed by kneader or roll mill without using the solvent, and then molded in the photosensitive resin plate with desirable thickness by extruder, injection molding device or press.

The thickness of the photosensitive resin layer (B) is normally in the range of 0.1 mm-10.0 mm.

<Infrared Ablation Layer (C)>

The infrared ablation layer (C) is a layer removable by infrared laser and masking non-infrared radiation. “Non-infrared radiation” is radiation other than infrared. For example, it may be visible ray, ultraviolet, X-ray and γ-ray, and ultraviolet is preferable.

The infrared ablation layer (C) comprises binder polymer consisting of the modified polyolefin (c1) described below, and the infrared absorbing material (c2).

Generally, various kinds of polymers may be used as the binder polymer, but the modified polyolefin (c1) is used as the binder polymer, and at least more than one polymer selected from the group comprising polyolefin modified by chlorine and/or maleic acid is used as the modified polyolefin in the present invention. The modified polyolefin (c1) may be single component or combination of two or more components.

“Modified polyolefin” described herein is a polymer with chlorine and/or maleic acid introduced in polyolefin resin. Particularly, the modified polyolefin is polyolefin that is chlorinated by introducing chlorine to polyolefin by a substitution or by addition reaction (chlorine-modified polyolefin), or polyolefin with maleic acid being graft-polymerized (maleic acid-modified polyolefin), or polyolefin that is subjected to both modifications.

Chlorine-modified polyolefin and maleic acid-modified polyolefin may be obtained by publicly known methods. For example, chlorine-modified polyolefin could be obtained by dispersing polyolefin to the solvent and injecting chlorine gas into the solvent in the presence of catalyst or ultraviolet irradiation. Polyolefin modified with both chlorine and maleic acid may be obtained by graft polymerizing the maleic acid after chlorinating the polyolefin. It could also be obtained by chlorination of polyolefin after it is graft polymerized with maleic acid.

Examples of this modified polyolefin (c1) may be modified polyolefin selected from the polymer group consisting of chlorinated polyolefin, maleic acid-modified chlorinated polyolefin, chlorinated polypropylene-acryl copolymer, maleic acid-modified polypropylene, chlorinated polyethylene and chlorinated EVA (ethylene-vinyl acetate copolymer).

The modified polyolefin (c1) used in the present invention preferably has chlorine modified rate (i.e. chlorine content determined by JISK7229 (a quantifying method of chlorine in chlorine-contained resin)) in the range of 3-70%, and maleic acid modified rate (i.e. maleic acid content determined by former JISK5407 (a paint component examining method)) in the range of 0.5-10%. Chlorine and maleic acid contents in the said ranges are preferable to maintain forming processability, heat resistance, chemical resistance, scratch resistance, flexibility, adhesiveness to the photosensitive resin layer and solubility to the flexographic developing solvent of the infrared ablation layer (C). Chlorine and maleic acid contents lower than lower limit of said ranges are not preferable because it leads to the decrease of forming processability, heat resistance, scratch resistance and solubility to the flexographic developing solvent of the infrared ablation layer (C). Chlorine and maleic acid contents higher than upper limit of said ranges are not preferable because it leads to the decrease of forming processability, adhesion to the photosensitive resin layer, flexibility and chemical resistance of infrared ablation layer (C).

The modified polyolefin (c1) used in the present invention is preferred to have 5,000-250,000 weight-average molecular weight (Mw) that is determined by gel-permeation chromatography method in polystyrene basis. The weight-average molecular weight (Mw) in said range is preferable to maintain forming processability, mechanical property, heat resistance, chemical resistance, scratch resistance and flexibility of infrared ablation layer (C) and to prevent from occurring fine wrinkles, scratches and cracks made on infrared ablation layer (C). The weight-average molecular weight (Mw) lower than lower limit of said range is not preferable because it leads to the decrease of mechanical property and scratch resistance of the infrared ablation layer (C). The weight-average molecular weight (Mw) higher than upper limit of said range is not preferable because it leads to the decrease of forming processability and flexibility of the infrared ablation layer (C).

The modified polyolefin (c1) used in the present invention preferably have 40° C.-300° C. softening point determined by mercury displacement method. Softening point in said range is preferable to maintain forming processability, heat resistance, scratch resistance and flexibility of the infrared ablation layer (C) and is preferable because adhesion property of the infrared ablation layer (C) occurs. Softening point lower than lower limit of said range is not preferable because it leads to the decrease of heat resistance and scratch resistance of the infrared ablation layer (C), and adhesion property of the infrared ablation layer (C) increases. Softening point higher than upper limit of said range is not preferable because it leads to the decrease of forming processability and flexibility of the infrared ablation layer (C).

The infrared ablation layer (C) consists of said modified polyolefin (c1) as the binder polymer has excellent adhesiveness to the photosensitive resin layer (B) and flexibility. It also has excellent detachability from the cover film (D) and has fine solubility to generally-used flexographic developing solvents.

The infrared ablation layer (C) is a layer removable by infrared laser, and also contains the infrared-absorbing material (c2) in addition to said modified polyolefin. Elemental substance or compound with strong absorption in the range of normally 750-2000 nm can be used as the infrared absorbing material (c2). For example, inorganic pigments such as carbon black, graphite, copper chromite and chromium oxide and dyes such as polyphthalocyanine compounds, cyanine dye and metal thiolate may be used. The infrared-absorbing material (c2) may be single component or combination of two or more components.

The infrared ablation layer (C) is a layer masking non-infrared radiation, and may contain non-infrared radiation masking substance. For example, substance reflecting or absorbing non-infrared radiation such as ultraviolet may be used as masking substance of non-infrared radiation, and its specific examples are ultraviolet absorbing agent, carbon black and graphite. Carbon black and graphite are substances exemplified as the infrared absorbing material (c2) and these substances could act as masking substances of non-infrared radiation. As such, the infrared absorbing material (c2) with a function to mask non-infrared radiation may be used as masking substances of non-infrared radiation.

In addition to the modified polyolefin (binder polymer) (c1) and the infrared absorbing material (c2), polymer other than modified polyolefin may be used in the infrared ablation layer (C), if necessary. For example, polymers that could be used with the modified polyolefin (c1) are acryl polymer, urethane polymer, polyester polymer, amino polymer, epoxy polymer, polyamide polymer, fibrin polymer, polyvinylbutyral, polyvinylacetal polymer, vinyl chloride, vinylidene chloride polymer, alkyd polymer, elastomer polymer, hard resin and natural resin. In addition, one or more additives such as parting agent, dispersing agent, coloring agent, surface conditioner, thickener, lubricant, wetting agent, anti-static agent, crosslinking agent, defoaming agent, antifoaming agent and adhesiveness imparting agent may be added, if necessary.

Here, a forming method of the infrared ablation layer (C) when using carbon black, which functions as both infrared absorbing substance and non-infrared radiation masking substance, is described as an example. Following method is effective; binder polymer solution is prepared by using appropriate solvent; and carbon black is dispersed in said binder polymer solution; dispersion obtained are coated on the cover film (D) such as polyester film; then, this cover film with infrared ablation layer is laminated or pressed to the photosensitive resin layer and the infrared ablation layer is transferred.

In order to increase adhesiveness of the photosensitive resin layer (B) and the infrared ablation layer (C), surface of the infrared ablation layer (C) with said cover film attached, which contacting with the photosensitive resin layer (B), may be improved by corona surface treatment or plasma surface treatment.

A dispersing method for beads mill, roll mill, high speed stirring mill and sonication is effective as a method for dispersing carbon black in binder polymer solution. Alternatively, a method for dissolving the binding polymer and carbon black in the solvent after premixing the binding polymer and carbon black by extruder or kneader is also effective for excellent dispersion of carbon black. Also, in order to increase disperse of carbon black, a dispersing agent may be used to a degree not to affect its properties and surface of carbon black may be treated.

The infrared absorbing material (c2) is added to the infrared ablation layer (C) in the amount such that it can give sensitivity enough to remove the infrared ablation layer (C) by laser beam. For example, content of the infrared absorbing material (c2) in the infrared ablation layer (C) preferably in the range of 10-70 mass %, and more preferably 20-60 mass % to 100 mass % of the infrared ablation layer (C). Content of the infrared absorbing material (c2) in said range is preferable because the balance of plotting sensitivity by infrared laser, mask effect of non-infrared radiation, flexibility and mechanical property of the infrared ablation layer (C) is excellent.

Adding amount of non-infrared radiation masking substance is preferably selected so that the infrared ablation layer (C) can achieve desirable optical density. Generally, non-infrared radiation masking substance may be added so that optical density is equal to or more than 2.5, and preferably is equal to or more than 3.5.

Dried coating weight of the infrared ablation layer (C) should be determined after consideration of plotting sensitivity by infrared laser and non-infrared radiation masking effect, but it is normally in the range of 0.1 g/m²−20 g/m², and preferably in the range of 1 g/m²−5 g/m².

<Cover Film (D)>

In the laminate of the present invention, the cover film (D) is placed on the infrared ablation layer (C). The cover film (D) is not limited as long as it could protect the photosensitive resin laminate. For example, polyester film and polyolefin film such as polyethylene film and polypropylene film may be used. The cover film (D) is present in the purpose of protecting the photosensitive resin layer (B) and the infrared ablation layer (C) from scratch and stain, and it is removed before plotting by infrared laser. Considering film strength and dimension stability, polyester film is preferable.

Considering film strength and dimension stability, the thickness of the cover film (D) is preferably in the range of 50-200 um, and more preferably 75-150 um.

In order to improve the detachment of the infrared ablation layer (C) and the cover film (D), cover film with detaching treatment performed may be used, if necessary.

<Preparation of the Photosensitive Resin Laminate for Flexographic Plate>

A preparing method of the photosensitive resin laminate for flexographic plate in the present invention is not specially limited. The laminate of the present invention could be prepared by applying the coating solution of the infrared ablation layer comprising the modified polyolefin (c1) and the infrared absorbing material (c2) on the cover film (D) to prepare the cover film with the infrared ablation layer; molding the photosensitive resin plate by using photosensitive resin composition comprising thermoplastic elastomer, polymerizable unsaturated monomer and photopolymerization initiator; heat-laminating the film as the support layer on one side of the photosensitive resin layer; and heat-laminating the cover film with the infrared ablation layer so that the photosensitive resin layer and the infrared ablation layer come into contact. Furthermore, coating solution of the infrared ablation layer comprising said (c1) and (c2) may be directly coated to the photosensitive resin layer (B).

<Uses of the Photosensitive Resin Laminate for Flexographic Plate>

One of the use embodiments of the photosensitive resin laminate for flexographic plate of the present invention is explained below.

The laminate of the present invention is used to prepare the flexographic plate. In the laminate of the present invention, the flexographic plate could be obtained by exposing the laminate of the present invention to non-infrared radiation from the support layer (A) side thereof (back exposure step); detaching the cover film (D) from the infrared ablation layer (C) (detaching step); selectively removing apart of the infrared ablation layer (C) based on e.g. image information digitized by computer, and forming (plotting) the pattern (image)(laser ablation step); exposing the laminate of the present invention to non-infrared radiation from the infrared ablation layer (C) side thereof, which was pattern-formed (image plotted) by infrared laser (relief exposure step); washing/removing the trace of the infrared ablation layer (C) and non-exposed part of the photosensitive resin layer (B) (developing step); removing the developing solvent by dryer (drying step); removing adhesiveness of surface of the plate and exposing ultraviolet to the non-harden part of the plate due to harden the part (surface treatment and post-exposure steps).

Infrared laser with wavelength of 750-2000 nm may be used as infrared laser used in the laser ablation step. Semiconductor laser of 750-880 nm or Nd-YAG laser of 1064 nm is normally used as this type of infrared laser. Generating unit of these lasers is controlled by computer with driving unit, and digitized image information could be plotted by selectively removing this layer (C) on the photosensitive resin layer (B).

There are visible light, ultraviolet, X-ray and γ-ray etc. as non-infrared radiation used in the relief exposure step and the back exposure step, but ultraviolet is preferable, and ultraviolet with wavelength of 315 nm-400 nm, which is referred to UV-A, is more preferable. There are ultraviolet LED, low-pressure mercury lamp, high-pressure mercury lamp, ultraviolet florescent lamp, carbon arc lamp, xenon lamp and sun light etc. as source of ultralight. Desired relief image may be obtained by exposing non-infrared radiation such as ultraviolet to the laminate of the present invention from image side thereof (relief exposure), but entire exposure from the support layer (A) side (back exposure) is effective to stabilize relief image from stress when washing/removing the non-harden part.

For example, the developing solvent used in the developing step may be chlorine organic solvent such as 1,1,1-trichloroethane, tetrachloroethylene, trichloroethylene and dichloroethylene, ester such as heptylacetate and 3-methoxybutylacetate, solvent naphtha such as paraffin oil and naphthene oil and hydrocarbon such as toluene and decahydronaphthalene. Also, alcohol such as propanol, butanol, pentanol, octanol or benzyl alcohol may be mixed with these solvents. Washing/removing the trace of the infrared ablation layer (C) and the non-exposed part of the photosensitive resin layer (B) may be performed by jet from nozzle or by brushing with brush.

The flexographic plate obtained by the above steps can be finished by rinsing, and treating surface of the plate and by post-exposing after drying, if necessary.

### Examples

Examples of the present invention will be described below with more details, but the photosensitive resin laminate for flexographic plate of the present invention is not limited to these examples. Also, in description below, the word “parts” means “parts by mass” if there is no specific explanation.

(1) Modified Polyolefin (c1)

Chlorine content of chlorine-modified polyolefin was calculated by JISK7229 (a quantifying method of chlorine in resin comprising chlorine) determination. Unit of chlorine content is percent by weight. Also, maleic acid content was calculated by former JISK5407 (paint component examining method) determination.

Weight-average molecular weight (Mw) of the modified polyolefin (c1) is a weight-average molecular weight converted to polystyrene determined by gel-permeation chromatography method (Tosoh Corporation, HLC-8120).

Developing solvent: Tetrahydrofuran

Determining temperature: 40° C.

Column: TSKgel GMHx1

Softening point temperature of the modified polyolefin (c1) is a softening point temperature determined by a mercury displacement method.

### Preparation of Infrared Ablation Layer

### Preparation Example 1

41 parts of toluene was added to heating air-tight container with stirring device; 3.0 parts of Hardlen13-LP was added as the modified polyolefin (c1) while stirring; and stirring and dissolving were performed under 40° C. (first step). After cooling to room temperature, 6.0 parts of PrinteX35, which is carbon black, as the infrared absorbing material (c2) and appropriate amount of a dispersing agent are added; and after premixing, dispersion of carbon black was performed using sand mill for 90 minutes (second step). Then, it was heated to 40° C. once again; 38.8 parts of toluene, 3.0 parts of methylethylketone and 8.2 parts of Hardlen13-LP as the modified polyolefin (c1) are added; and stirring and dissolving are performed (third step); and coating solution of the infrared ablation layer with mass ratio of carbon black (the infrared absorbing materiel (c2):binder (the modified polyolefin (c1))=35:65 was prepared. This coating solution was coated on polyester film (trade name “Lumirror125T60”; Toray Industries, Inc.) of 125 um thickness with bar coater so that dried coating weight is 2.8 g/m², and the cover film with the infrared ablation layer is obtained.

### Preparation Examples 2-12

The cover films with the infrared ablation layer were prepared by same method as preparation example 1 except kind of each material and its used amount in first to third steps is changed as described in Table 1 and 2.

TABLE 1

| | | | Preparation | Preparation | Preparation | Preparation | Preparation | Preparation |
|---|---|---|---|---|---|---|---|---|
| | | | Example 1 | Example 2 | Example 3 | Example 4 | Example 5 | Example 6 |
| First step | Solvent | toluene | 41.0 | 29.0 | 41.0 | 41.0 | 41.0 | 41.0 |
| | | normal propyl alcohol | | | | | | |
| | | methyl ethyl ketone | | | | | | |
| | Modified polyolefin | Hardlen 13-LP | 3.0 | | 3.0 | 3.0 | 3.0 | 3.0 |
| | | Superchlon B | | 15.0 | | | | |
| | | Harden P-5528 | | | | | | |
| | Other binder polymer | Atactic polypropylene | | | | | | |
| | | Macromelt6900 | | | | | | |
| | | Asaflex810 | | | | | | |
| Second | Infrared absorbing material (c3) | PrinteX35 | 6.0 | 6.0 | 6.0 | 6.0 | 6.0 | 6.0 |
| step | Dispersing agent | Dispersing agent | appropriate | appropriate | appropriate | appropriate | appropriate | appropriate |
| | | | amount | amount | amount | amount | amount | amount |
| Third step | Solvent | toluene | 38.8 | 38.8 | 38.8 | 38.8 | 38.8 | 30.8 |
| | | methyl ethyl ketone | 3.0 | 3.0 | 3.0 | 3.0 | 3.0 | 3.0 |
| | | normal butyl alcohol | | | | | | |
| | Modified polyolefin | Hardlen 13-LP | 8.2 | 8.2 | 6.2 | 6.2 | 6.2 | 6.2 |
| | | Superchlon HP-205 | | | 2.0 | | | |
| | | Superchlon HE-515 | | | | 2.0 | | |
| | | Harden CY-9124P | | | | | 2.0 | |
| | | Hardlen P-5528 | | | | | | 10.0 |
| | | Colnova MPO-B502 | | | | | | |
| | Other binder polymer | Dianal BR-90 | | | | | | |
| | | Atactic polypropylene | | | | | | |
| | | Macromelt6900 | | | | | | |
| | | Asaflex810 | | | | | | |

TABLE 2

| | | | Preparation | Preparation | Preparation | Preparation | Preparation | Preparation |
|---|---|---|---|---|---|---|---|---|
| | | | Example 7 | Example 8 | Example 9 | Example 10 | Example 11 | Example 12 |
| First step | Solvent | toluene | 41.0 | 29.0 | 41.0 | 41.0 | 40.0 | 24.0 |
| | | normal propyl alcohol | | | | | 10.0 | |
| | | methyl ethyl ketone | | | | | | 24.0 |
| | Modified polyolefin | Hardlen 13-LP | 3.0 | | 3.0 | | | |
| | | Superchlon B | | | | | | |
| | | Hardlen P-5528 | | 15.0 | | | | |
| | Other binder polymer | Atactic polypropylene | | | | 3.0 | | |
| | | Macrome1t6900 | | | | | 4.0 | |
| | | Asaflex810 | | | | | | 5.0 |
| Second | Infrared absorbing material (c3) | PrinteX35 | 6.0 | 6.0 | 6. 0 | 6.0 | 6.0 | 7.0 |
| step | Dispersing agent | Dispersing agent | appropriate | appropriate | appropriate | appropriate | appropriate | appropriate |
| | | | amount | amount | amount | amount | amount | amount |
| Third step | Solvent | toluene | 30.8 | 6.0 | 30.8 | 38.8 | 1.5 | 16.0 |
| | | methyl ethyl ketone | 3.0 | 3.0 | 3.0 | 3.0 | | 16.0 |
| | | normal butyl alcohol | | | | | 31.5 | |
| | Modified polyolefin | Hardlen 13-LP | 6.2 | | 7.7 | | | |
| | | Superchlon HP-205 | | | | | | |
| | | Superchlon HE-515 | | | | | | |
| | | Hardlen CY-9124P | | | | | | |
| | | Hardlen P-5528 | | 41.0 | | | | |
| | | Colnova MPO-B502 | 10.0 | | | | | |
| | Other binder polymer | Dianal BR-90 | | | 0.5 | | | |
| | | Atactic polypropylene | | | | 8.2 | | |
| | | Macromelt6900 | | | | | 7.2 | |
| | | Asaflex810 | | | | | | 8.0 |

Numeric values of Table 1 and 2 indicate blending amount (unit: part by weight).

“Hardlen13-LP” Chlorinated polypropylene; Weight-average molecular weight: 220,000, chlorinated rate: 26%, softening point: 79° C.; Toyobo Co., Ltd.

“Superchlon B” Chlorinated EVA, 20% toluene solution; Weight-average molecular weight: 100,000, chlorinated rate: 27%, softening point: 57° C.; Nippon Paper Industries Co., Ltd.

“Superchlon HP-205” Chlorinated polypropylene; Weight-average molecular weight: 30,000, chlorinated rate: 68%, softening point: 250-300° C.; Nippon Paper Industries Co., Ltd.

“Superchlon HP-515” Chlorinated polyethylene; Weight-average molecular weight: 25,000, chlorinated rate: 67%, softening point: 250-300° C.; Nippon Paper Industries Co., Ltd.

“HardlenCY-9124P” Maleic acid-modified chlorinated polypropylene; Weight-average molecular weight: 60,000, chlorinated rate: 24%, maleic acid rate: 1.6%, softening point: 90° C.; Toyobo Co., Ltd.

“HardlenP-5528” Chlorinated polypropylene-acryl copolymer, 20% xylene solution; Weight-average molecular weight 60,000, chlorinated rate 15%, softening point: 90° C.; Toyobo Co., Ltd.

“Colnova MPO-B502” maleic acid-modified polypropylene, 20% methylcyclohexane/ethyl acetate solution; Weight-average molecular weight: 90,000, maleic acid rate: 2%, softening point: 90° C.; Nihon Cima Co., Ltd.

“PrinteX35” carbon black; Orion Engineered Carbons.

“Dianal BR-90” acryl polymer; weight-average molecular weight: 230,000, glass transition point: 65° C.; Mitsubishi Rayon Co., Ltd.

“Atactic polypropylene” non-modified atactic polypropylene; weight-average molecular weight: 30,000, softening point: 105° C.

“Macromelt6900” polyamide resin; Henkel Japan Ltd.

“Asaflex810” styrene-butadiene block copolymer; Asahi Kasei Chemicals Corporation.

<Preparation of Photosensitive Resin Composition>

60 parts of JSR TR2827 (JSR Corporation, styrene-butadiene-styrene block copolymer), 30 parts of B-2000 (Nippon Soda Co., Ltd.), 6 parts of 1,6-hexanediol acrylate, 2 parts of 1,6-hexanediol dimethacrylate, 2 parts of 2,2-dimethoxy-1,2-diphenylethan-1-one, 0.4 part of p-methoxyphenol, 0.3 part of n-octadecyl-3-(3,5-dimethyl-tert-butyl-4-hydroxyphenyl) propionate and 0.003 part of “C.I. Solvent Red 180” are mixed using pressure-type kneader under 150° C. for 40 minutes to obtain photosensitive resin composition.

<Preparation of the Photosensitive Resin Laminate for Flexographic Plate>

The above photosensitive resin composition was sandwiched between silicon-detached polyester films with 125 um thickness, and was pressed in 100-150 kg/cm² for four minutes under 100-120° C. by hot press using 1.6 mm spacer to mold the photosensitive resin plate for flexographic plate (the photosensitive resin layer (B)).

Polyester film (trade name “Lumirror125T60”; Toray Industries, Inc.) of 125 um thickness was heat-laminated under 60° C. as the support layer to one side of this photosensitive resin laminates for flexographic plate. Then, the cover films with the infrared ablation layer prepared in preparation examples 1-12 as the infrared ablation layer and the cover film were heat-laminated to the other side of this photosensitive resin layer under 60° C. so that the photosensitive resin layer and the infrared ablation layer are attached, thereby preparing the photosensitive resin plate for flexographic plate. The laminates comprising cover film with the infrared ablation layer prepared in preparation examples 1-9 are Examples 1-9, and the laminates comprising the cover film with the infrared ablation layer prepared in preparation examples 10-12 are Comparative examples 1-3.

[Preparation of Flexographic Plates]

The photosensitive resin laminate for flexographic plate can be obtained by 250 mJ/cm² back-exposing from the support layer side thereof to the laminate using low-pressure mercury ultraviolet lamp (TLK40W/10-R, Royal Phillips), which has center wavelength of around 365 nm, on JE-42, 60-P exposure device (Nihon Denshi Seiki Co., Ltd.). Then, the cover film of the photosensitive resin laminates for flexographic plate was detached.

After detaching the cover film, this photosensitive resin laminate was fixed to drum cylinder of infrared laser plotting device (CDI Spark 2120, Esko-graphics), and was irradiated by infrared laser of Nd-YAG laser (center wavelength of 1064 nm) in order to selectively remove the infrared ablation layer. 1%-100% of halftone pattern of each 80LPI, 100LPI, 133LPI, 150LPI and 175LPI, thin line or reverse line of 1.0 mm-0.1 mm width and text image pattern of 4 pt-12 pt were plotted, and then relief exposure of 9000 mJ/cm² was performed using the exposure device described above.

Subsequently, developing process was performed using hydrocarbon solvent for flexographic development (a mixture of solvent naphtha/decahydronaphthalene/benzyl alcohol/octanol with mass ratio of 40:40:15:5) and JW-A3-P developing device (flat-type flexographic plate developing device, Nihon Denshi Seiki Co., Ltd.) for four minute under 30° C. in liquid. After solvent development, the plate was dried for 120 minutes in hot air dryer under 60° C. to remove the developing solvent. After the drying was finished, ultraviolet exposure was further performed for plate surface treatment (removing viscosity) and postexposure to obtain flexographic plate.

<Evaluation of Photosensitive Resin Laminate for Flexographic Plate>

In prepared photosensitive resin laminate for flexographicplate, (1)-(5) described below were evaluated based on evaluation criteria described below. The results are indicated in Table 3 described below.

(1) Adhesiveness of the infrared ablation layer and the photosensitive resin laminate

⊚: Very strongly adhered

◯: Adhered in a strength that could be used without practical problem

Δ: Adhered in weak strength, and sometimes infrared ablation layer was detached from the photosensitive resin layer.

X: Did not adhere at all.

(2) Detachability of the cover film

⊚: The cover film can be detached very smoothly

◯: The cover film can be detached smoothly without practical problem.

Δ: Apart of the ablation layer remained on the cover film side when detaching the cover film.

X: It was difficult to detach the cover film.

(3) Flexibility of the infrared ablation layer

⊚: No fine wrinkle or scratch is made on the surface of the ablation layer when the plate was handled in plate preparation process.

◯: No fine wrinkle or scratch that will matter in practice is made when the plate was handled in plate preparation process.

Δ: Fine wrinkles or scratches are made when the plate was handled in plate preparation process.

X: Large wrinkles or scratches are made when the plate was handled in plate preparation process.

(4) Solubility to a solvent for flexographic plate development

⊚: The ablation layer was completely dissolved in the developing solvent.

◯: The ablation layer became submicroscopic film pieces and dispersed in the developing solvent without any practical problem.

Δ: The ablation layer was difficult to be dissolved, and large film pieces were floating.

X: The ablation layer was completely undissolved.

(5) Image reproducibility of obtained flexographic plates

◯: The image plotted on the infrared ablation layer of the photosensitive resin laminate was reproduced on obtained flexographic plates as relief image.

Δ: Preparation of the plate is possible, but pattern image plotted on the infrared ablation layer of the photosensitive resin laminate was not reproduced because of poor ablation or scratches, wrinkles or cracks etc. made in plate preparing process.

X: The plates could not be prepared, and thus the evaluation was not possible.

TABLE 3

| | Example | Example | Example | Example | Example | Example | Example | Example | Example | Comparative | Comparative | Comparative |
|---|---|---|---|---|---|---|---|---|---|---|---|---|
| | 1 | 2 | 3 | 4 | 5 | 6 | 7 | 8 | 9 | example 1 | example 2 | example 3 |
| Component ratio | | | | | | | | | | | | |
| of binder polymer | | | | | | | | | | | | |
| in infrared ablation | | | | | | | | | | | | |
| layer | | | | | | | | | | | | |
| Hardlen 13-LP | 100 | 73 | 82 | 82 | 82 | 82 | 82 | — | 95 | — | — | — |
| (Chlorinated | | | | | | | | | | | | |
| polypropyrene) | | | | | | | | | | | | |
| Superchlon B | — | 27 | — | — | — | — | — | — | — | — | — | — |
| (Chlorinated EVA) | | | | | | | | | | | | |
| SuperchlonHP-205 | — | — | 18 | — | — | — | — | — | — | — | — | — |
| (Chlorinated | | | | | | | | | | | | |
| polypropyrene) | | | | | | | | | | | | |
| SuperchlonHE-S15 | — | — | — | 18 | — | — | — | — | — | — | — | — |
| (Chlorinated | | | | | | | | | | | | |
| polyethylene) | | | | | | | | | | | | |
| Hardlen CY-9124P | — | — | — | — | 18 | — | — | — | — | — | — | — |
| (maleic acid- | | | | | | | | | | | | |
| modified | | | | | | | | | | | | |
| chlorinated | | | | | | | | | | | | |
| polypropyrene) | | | | | | | | | | | | |
| HardlenP-S528 | — | — | — | — | — | 18 | — | 100 | — | — | — | — |
| (chlorinated | | | | | | | | | | | | |
| polypropyrene- | | | | | | | | | | | | |
| acryl copolymer) | | | | | | | | | | | | |
| Colnova | — | — | — | — | — | — | 18 | — | — | — | — | — |
| MPO-B502 | | | | | | | | | | | | |
| (maleic acid- | | | | | | | | | | | | |
| modified | | | | | | | | | | | | |
| polypropyrene) | | | | | | | | | | | | |
| Dianal BR-90 | — | — | — | — | — | — | — | — | 5 | — | — | — |
| (acryl polymer) | | | | | | | | | | | | |
| Atactic | — | — | — | — | — | — | — | — | — | 100 | — | — |
| polypropylene | | | | | | | | | | | | |
| (non-modified | | | | | | | | | | | | |
| polypropyrene) | | | | | | | | | | | | |
| Macromelt6900 | — | — | — | — | — | — | — | — | — | — | 100 | — |
| (polyamide | | | | | | | | | | | | |
| polymer) | | | | | | | | | | | | |
| Asaflex810 | — | — | — | — | — | — | — | — | — | — | — | 100 |
| (SES polymer) | | | | | | | | | | | | |
| Performance | | | | | | | | | | | | |
| evaluation | | | | | | | | | | | | |
| Adhesiveness of | ◯ | ⊚ | ◯ | ◯ | ⊚ | ⊚ | ⊚ | ⊚ | ◯ | X | Δ | ⊚ |
| infrared ablation | | | | | | | | | | | | |
| layer and | | | | | | | | | | | | |
| photosensitive | | | | | | | | | | | | |
| resin layer | | | | | | | | | | | | |
| Detachability | ⊚ | ◯ | ⊚ | ⊚ | ◯ | ◯ | ◯ | ◯ | ◯ | Δ | Δ | X |
| of cover film | | | | | | | | | | | | |
| Flexibility of | ◯ | ◯ | ◯ | ◯ | ◯ | ◯ | ◯ | ◯ | ◯ | ◯ | Δ | Δ |
| infrared abiation | | | | | | | | | | | | |
| layer | | | | | | | | | | | | |
| Solubility to | ◯ | ◯ | ◯ | ◯ | ◯ | ◯ | ◯ | ◯ | ◯ | Δ | Δ | ⊚ |
| flexographic plate | | | | | | | | | | | | |
| developing agent | | | | | | | | | | | | |
| Image | ◯ | ◯ | ◯ | ◯ | ◯ | ◯ | ◯ | ◯ | ◯ | X | Δ | Δ |
| reproducibility | | | | | | | | | | | | |

Regarding the infrared ablation layer of Examples 1-9, the cover film were smoothly detachable, the plates were not damaged when the photosensitive resin laminate was lifted and there was no trace of detachment on the infrared ablation layer. Also, fine wrinkle or crack was not made on the surface of the infrared ablation layer during relief exposure or during preparation of plates, for fixing and unfixing photosensitive resin laminate to drum cylinder of infrared laser plotting device. The pattern images plotted on the infrared ablation layer of the photosensitive resin laminate were precisely reproduced on the obtained flexographic plates.

On the other hand, adhesiveness of the infrared ablation layer and the photosensitive resin layer is extremely weak, problems such as occurrence of air bubbles on interface because of detachment of the infrared ablation layer from the photosensitive resin layer, and problems because of the presence of whole or a part of the infrared ablation layer on the cover film side, have happened frequently in Comparative example 1. Although fine wrinkles or cracks were not made on the surface of the infrared ablation layer during relief exposure or during preparation of plates for fixing and unfixing the photosensitive resin laminate to drum cylinder of infrared laser plotting device, the solubility of the infrared ablation layer to the developing solvent for the flexographic plate was not enough, and thus relatively large film pieces were floating in the developing device and frequently reattached to the flexographic plate. From these problems, it was difficult to prepare the plates, and it was not possible to evaluate relief reproducibility after plate preparation.

In some cases of Comparative example 2, there was a problem that when the cover film was detached, whole or apart of the infrared ablation layer remained on the cover film side due to weak adhesiveness of the infrared ablation layer and the photosensitive resin layer. Also, in some cases, fine wrinkles or cracks were made on the surface of the infrared ablation layer during relief exposure or during preparation of plates for fixing and unfixing the photosensitive resin laminate to drum cylinder of infrared laser plotting device, the solubility of the infrared ablation layer to the developing solvent for the flexographic plate was not enough, and thus relatively large film pieces were floating in the developing device and frequently reattached to the flexographic plate. The cover film detachment problems and relief reproducibility problems caused by fine wrinkles and cracks etc. occurred during plate preparation were observed in the obtained flexographic plates.

Detachment of the cover film was strong in Comparative example 3, and thus detachment was difficult. Thus, the cover film could not be detached at once and required intermittent detachment, and thus the cover film remained on the infrared ablation layer, and in some cases, the photosensitive resin laminate itself was bended, thereby damages remained on the photosensitive resin laminate. Further, as same as Comparative example 2, fine wrinkles or cracks were made on the surface of the infrared ablation layer during relief exposure or during preparation of the plates for fixing and unfixing the photosensitive resin laminate to the drum cylinder of infrared laser plotting device, the flexibility of the infrared ablation layer was not enough. The cover film detachment problems and relief reproducibility problems caused by fine wrinkles and cracks etc. occurred during plate preparation were observed in the obtained flexographic plates.

<Evaluation of Sensitivity of Infrared Ablation Layer Against Infrared Laser>

Ablation treatment was performed by infrared laser with ablation energy indicated in Table 4 described below with respect to the photosensitive resin laminate for flexographic plate of Example 1, Comparative examples 2 and 3. Whether ablation is possible with low energy or not, i.e. evaluation of sensitivity to infrared laser, was performed by determining OD value (optical density) of ablation part. Further, “(1) OD value of support layer (A)+photosensitive resin layer (B)” in the Table is OD value when the infrared ablation layer is not originally laminated, and “(2) OD value of ablation part” is OD value of a part (area of 5 cm×5 cm) that the ablation layer is selectively removed after treatment of the photosensitive resin laminate for flexographic plate.

TABLE 4

| | Example 1 | | | Comparative example 2 | | | Comparative example 3 | | |
|---|---|---|---|---|---|---|---|---|---|
| | (1) OD value of | (2) OD | | (1) OD value of | (2) OD | | (1) OD value of | (2) OD | |
| Ablation | suppot layer (A) | value of | | support layer (A) | value of | | suppot layer (A) | value of | |
| energy | and photosensitive | ablation | | and photosensitive | ablation | | and photosensitive | ablation | |
| (J/cm²) | resin layer (B) | part | (2) − (1) | resin layer (B) | part | (2) − (1) | resin layer (B) | part | (2) − (1) |
| 3.4 | 0.30 | 0.32 | 0.02 | 0.46 | 0.48 | 0.02 | 0.30 | 0.33 | 0.03 |
| 3.2 | | 0.32 | 0.02 | | 0.48 | 0.02 | | 0.33 | 0.03 |
| 3.0 | | 0.32 | 0.02 | | 0.48 | 0.02 | | 0.33 | 0.03 |
| 2.8 | | 0.32 | 0.02 | | 0.48 | 0.02 | | 0.33 | 0.03 |
| 2.6 | | 0.32 | 0.02 | | 0.50 | 0.04 | | 0.35 | 0.05 |
| 2.4 | | 0.35 | 0.05 | | 0.53 | 0.07 | | 0.39 | 0.09 |
| 2.2 | | 0.40 | 0.10 | | 0.67 | 0.21 | | 0.50 | 0.20 |
| 2.0 | | 0.63 | 0.33 | | 1.02 | 0.56 | | 0.97 | 0.67 |

[Conditions for determination]
Ablation device: Esko-graphics, CDI Spark2120
Optical density (OD value) measuring instrument: X-rite, permiation densitometer 361T
[Condition of ablation]
Ablate 5 cm × 5 cm area of solid image

As Table 4 indicates, the difference between “(1) OD value of support layer (A)+photosensitive resin layer (B)” and “(2) OD value of ablation part” of the photosensitive resin laminate for the flexographic plate of Example 1 was small compared to Comparative examples 2 and 3, especially at low ablation energy. OD value will indicate large value when remaining amount of the infrared ablation layer on the photosensitive resin layer (B) is high. Thus, from these results, it could be understood that the photosensitive resin laminate for flexographic plate of Example 1 was neatly ablated even by low energy compared to Comparative examples 2 and 3, and thus the laminate is highly sensitive to infrared laser.

### INDUSTRIAL APPLICABILITY

The present invention relates to the photosensitive resin laminate for flexographic plate, which could be applied to the plate preparation method using infrared laser to directly plot the image information digitized on computer, and without using negative film, and it could be used broadly among the technical field of printing.

### DESCRIPTION OF SIGN

10 . . . Support layer (A)
20 . . . Photosensitive resin layer (B)
30 . . . Infrared ablation layer (C)
40 . . . Cover film (D)

1. A photosensitive resin laminate for flexographic plate consisting of;
a support layer (A),
a photosensitive resin layer (B) placed on said support layer (A) comprising thermoplastic elastomer, polymerizable unsaturated monomer, and photopolymerization initiator,
an infrared ablation layer (C) placed on said photosensitive resin layer (B) which is removable by infrared laser and masks non-infrared radiation, and
a cover film (D) placed on said infrared ablation layer (C),
wherein said infrared ablation layer (C) comprises modified polyolefin (c1) and infrared absorbing material (c2), and
wherein said modified polyolefin (c1) comprises at least more than one polymer selected from the group consisting of polyolefin modified by chlorine and/or maleic acid.

2. The photosensitive resin laminate for flexographic plate according to claim 1, wherein said modified polyolefin (c1) comprises at least more than one polymer selected from the polymer group consisting of chlorinated polypropylene, maleic acid-modified chlorinated polypropylene, chlorinated polypropylene-acryl copolymer, maleic acid-modified propylene, chlorinated polyethylene and chlorinated EVA (ethylene-vinyl acetate copolymer).

3. The photosensitive resin laminate for flexographic plate according to claim 1, wherein said modified polyolefin (c1) is chlorine-modified polyolefin with 3-70% chlorine-modified rate, maleic acid-modified polyolefin with 0.5-10% maleic acid-modified rate, or maleic acid-modified chlorinated polyolefin with 3-70% chlorine-modified rate and 0.5-10% maleic acid-modified rate.

4. The photosensitive resin laminate for flexographic plate according to claim 1, wherein a weight-average molecular weight (Mw) of said modified polyolefin (c1) is 5,000-250,000.

5. The photosensitive resin laminate for flexographic plate according to claim 1, wherein a softening point of said modified polyolefin (c1) is 40° C.-300° C.

6. The photosensitive resin laminate for flexographic plate according to claim 1, wherein a content of said infrared absorbing material (c2) is in the range of 10-70% by mass with respect to said infrared ablation layer (C).

7. The photosensitive resin laminate for flexographic plate according to claim 1, wherein said support layer (A) is polyester film.

8. The photosensitive resin laminate for flexographic plate according to claim 1, wherein said cover film (D) is polyester film.
